(19) United States
(12) Patent Application Publication
(10) Pub. No.: US 2022/0285217 A1
(43) Pub. Date: Sep. 8, 2022

(54) WAFER THINNING METHOD

(71) Applicant: Orient Semiconductor Electronics, Limited, Kaohsiung (TW)

(72) Inventors: YUEH-MING TUNG, Kaohsiung (TW); CHIA-MING YANG, Kaohsiung (TW); GUAN-LIN PAN, Kaohsiung (TW); JUNG-WEI CHEN, Kaohsiung (TW); JIAN-DE LEU, Kaohsiung (TW)

(21) Appl. No.: 17/215,417

(22) Filed: Mar. 29, 2021

(30) Foreign Application Priority Data
Mar. 3, 2021 (TW) 110107568

(51) Int. Cl. H01L 21/78; H01L 21/02; H01L 21/304

(52) U.S. Cl. CPC H01L 21/78; H01L 21/02013; H01L 21/304

(57) ABSTRACT

The wafer thinning method of the present disclosure includes: providing a wafer having a front surface and a back surface opposite to the front surface; grinding the back surface of the wafer with a grinding bit to thin the wafer to a predetermined thickness; dicing the wafer with a dicing blade; ablating the wafer by performing a chemical solution or plasma process on the back surface of the wafer to thin the wafer; and separating the wafer into a plurality of dies.

### RELATED APPLICATION

The present application is based on and claims priority to Taiwanese Application Number 110107568, filed Mar. 3, 2021, the disclosure of which is hereby incorporated by reference herein in its entirety.

### BACKGROUND

### 1. Technical Field

This disclosure relates to a wafer processing method, and more particularly relates to a wafer thinning method.

### 2. Description of the Related Art

Semiconductor components are becoming shorter and smaller, the thickness of wafers becomes smaller and smaller accordingly. The current wafer thinning method needs to be completed through grinding technology. However, the ratio of the circuit layer to the silicon layer on wafer cannot meet specific requirements. As a result, the wafers after grinding are prone to cracks and the production yield is reduced according.

### SUMMARY

In view of the above, the present disclosure provides a wafer thinning method, which may thin the wafer to a desired thickness without cracking the wafer.

The wafer thinning method according to the first embodiment of the present disclosure includes: providing a wafer having a front surface and a back surface opposite to the front surface; grinding the back surface of the wafer with a grinding bit to thin the wafer to a predetermined thickness; dicing the wafer with a dicing blade; ablating the wafer by performing a chemical solution or plasma process on the back surface of the wafer to thin the wafer; and separating the wafer into a plurality of dies.

The wafer thinning method according to the second embodiment of the present disclosure includes: providing a wafer having a front surface and a back surface opposite to the front surface; grinding the back surface of the wafer with a grinding bit to thin the wafer to a predetermined thickness; dicing the wafer with laser beams; ablating the wafer by performing a chemical solution or plasma process on the back surface of the wafer to thin the wafer; and separating the wafer into a plurality of dies.

According to the wafer thinning method of the present disclosure, the wafer may be thinned to a desired thickness without cracking the wafer.

The foregoing, as well as additional objects, features and advantages of the disclosure will be more readily apparent from the following detailed description, which proceeds with reference to the accompanying drawings.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 to 12 illustrate the steps of the wafer thinning method according to the first embodiment of the present disclosure.

FIGS. 13 to 22 illustrate the steps of the wafer thinning method according to the second embodiment of the present disclosure.

### DETAILED DESCRIPTION OF THE PREFERRED EMBODIMENT

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatial relative terms, such as “beneath.” “below,” “lower,” “above,” “upper” and the like, may be used herein for ease of description to describe one element or feature's relationship to another element(s) or feature(s) as illustrated in the figures. The spatial relative terms are intended to encompass different orientations of the device in use or operation in addition to the orientation depicted in the figures. The apparatus may be otherwise oriented (rotated 90 degrees or at other orientations) and the spatial relative descriptors used herein may likewise be interpreted accordingly.

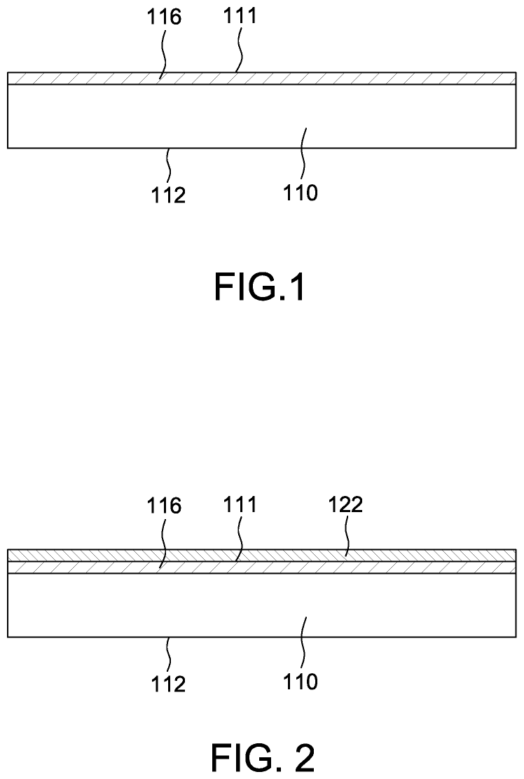

With reference to FIGS. 1 to 12, which illustrate the steps of the wafer thinning method according to the first embodiment of the present disclosure.

As shown in FIG. 1, an unprocessed wafer 110 is provided first. The wafer 110 has a front surface 111 and a back surface 112 opposite to the front surface 111. A circuit layer 116 is provided on the front surface 111 of the wafer 110.

Next, as shown in FIG. 2, a protective film 122 is attached to the front surface 111 of the wafer 110 to protect the circuit layer 116 from damage.

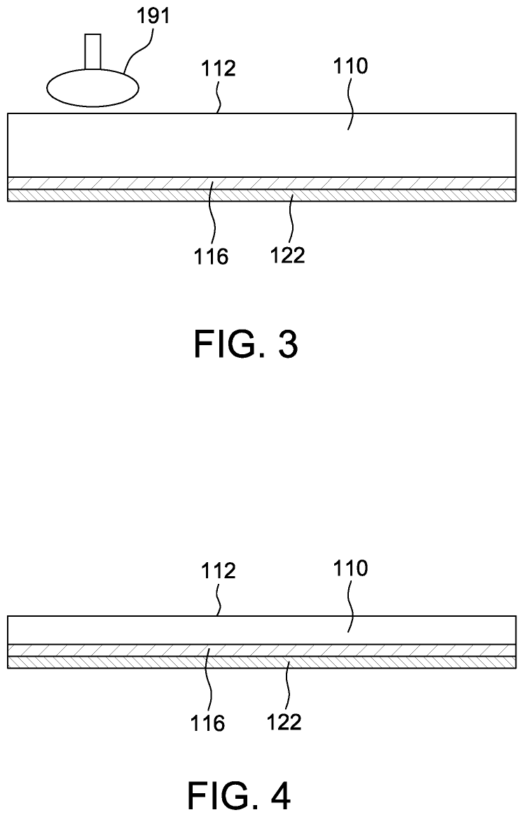

Subsequently, as shown in FIG. 3, the protective film 122 on the wafer 110 is held by a holding surface of a worktable (not shown), and the back surface 112 of the wafer 110 is ground with a grinding bit 191 to thin the wafer 110 to a predetermined thickness. FIG. 4 shows that the wafer 110 has been thinned to the predetermined thickness after being ground.

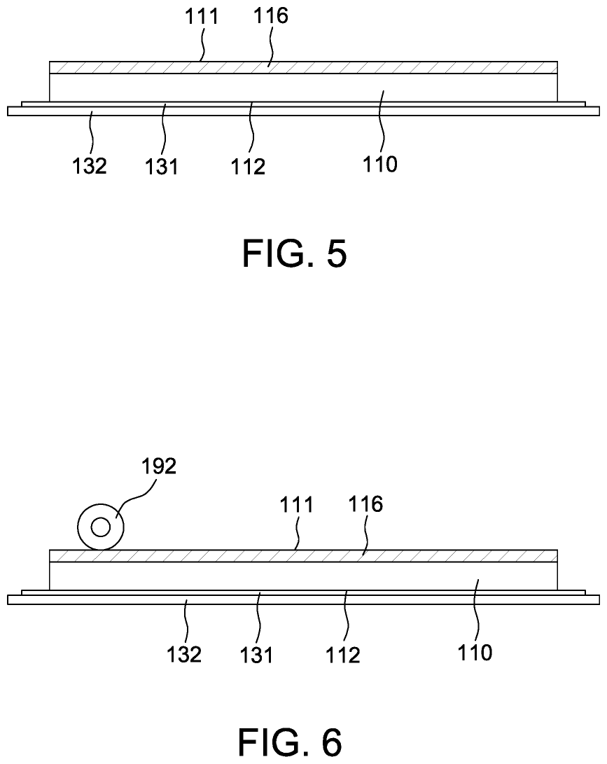

Next, as shown in FIG. 5, an attach film 131 is attached to the back surface 112 of the thinned wafer 110, and the wafer 110 is fixed to a frame 132. The protective film 122 is removed from the front surface 111 of the wafer 110.

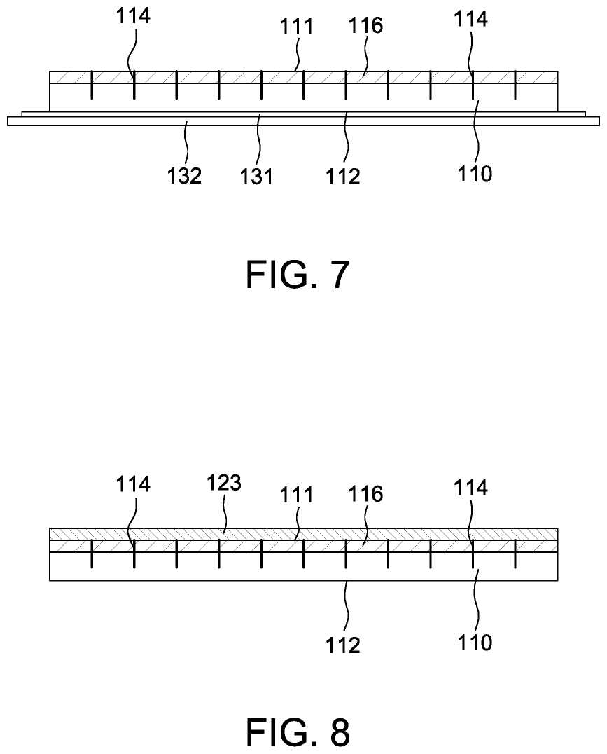

Next, as shown in FIG. 6, the wafer 110 is mechanically diced. More specifically, the frame 132 is fixed and a worktable is used to hold the back surface 112 of the wafer 110 (not shown). A dicing blade 192 is then used to dice the wafer 110 along predetermined cutting lines (not shown) on the front surface 111 of the wafer 110 so as to scribe a plurality of dicing grooves having a predetermined depth. FIG. 7 shows that the wafer 110 has a plurality of dicing grooves 114 formed on the front surface 111 thereof after being diced by the dicing blade 192.

In one embodiment, the rotation speed of the dicing blade 192 during dicing is 30000-55000 rpm. The each dicing groove 114 has a depth of (25-350)±5 μm, and a width of (10-60)±3 μm.

Subsequently, as shown in FIG. 8, the attach film 131 and the frame 132 are removed from the back surface 112 of the wafer 110. A protective film 123 is attached to the front surface 111 of the wafer 110.

In another embodiment, the protective film 123 may be attached to the front surface 111 of the wafer 110 first, and then the attach film 131 and the frame 132 are removed from the back surface 112 of the wafer 110.

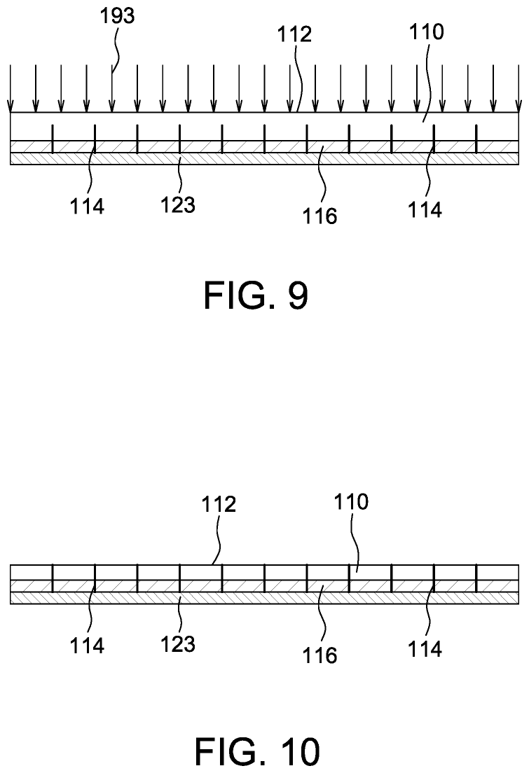

Afterwards, as shown in FIG. 9, a chemical solution or plasma process 193 is performed on the back surface 112 of the wafer 110 to ablate the wafer 110 so as to thin the wafer 110 to a required thickness. FIG. 10 shows that the wafer 110 has been thinned to the required thickness.

In one embodiment, the wafer 110 has a thickness of (20-300)±3 μm after subjection to the chemical solution or plasma process 193.

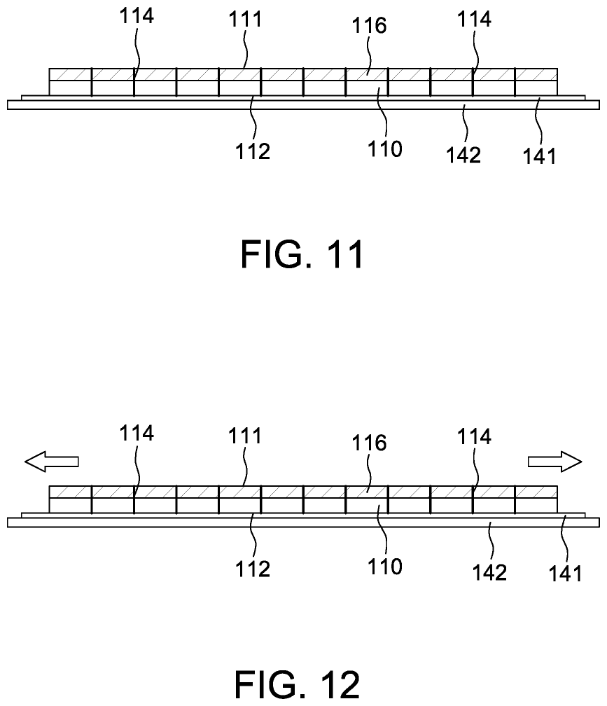

Next, as shown in FIG. 11, an attach film 141 is attached to the back surface 112 of the thinned wafer 110, and the wafer 110 is fixed to a frame 142. The protective film 123 is removed from the front surface 111 of the wafer 110.

Finally, as shown in FIG. 12, the frame 142 is fixed and outward forces are applied to the attach film 141 to expand the wafer 110 so that the wafer 110 is separated into a plurality of dies along the dicing grooves 114.

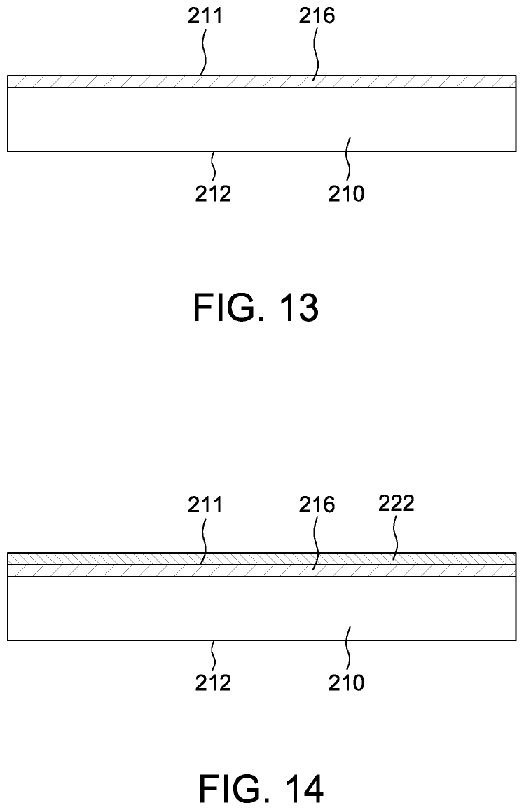

With reference to FIGS. 13 to 22, which illustrate the steps of the wafer thinning method according to the second embodiment of the present disclosure.

As shown in FIG. 13, an unprocessed wafer 210 is provided first. The wafer 210 has a front surface 211 and a back surface 212 opposite to the front surface 211. A circuit layer 216 is provided on the front surface 211 of the wafer 210.

Next, as shown in FIG. 14, a protective film 222 is attached to the front surface 211 of the wafer 210 to protect the circuit layer 216 from damage.

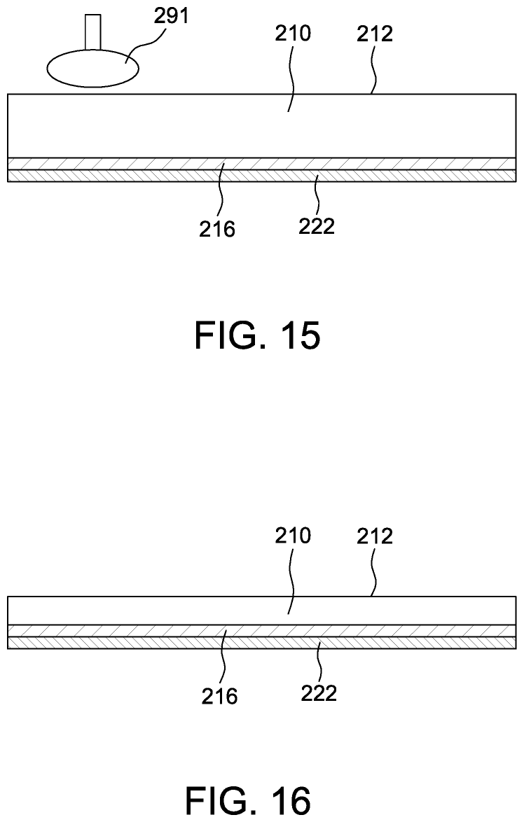

Subsequently, as shown in FIG. 15, the protective film 222 on the wafer 210 is held by a holding surface of a worktable (not shown), and the back surface 212 of the wafer 110 is ground with a grinding bit 291 to thin the wafer 210 to a predetermined thickness. FIG. 16 shows that the wafer 210 has been thinned to the predetermined thickness after being ground.

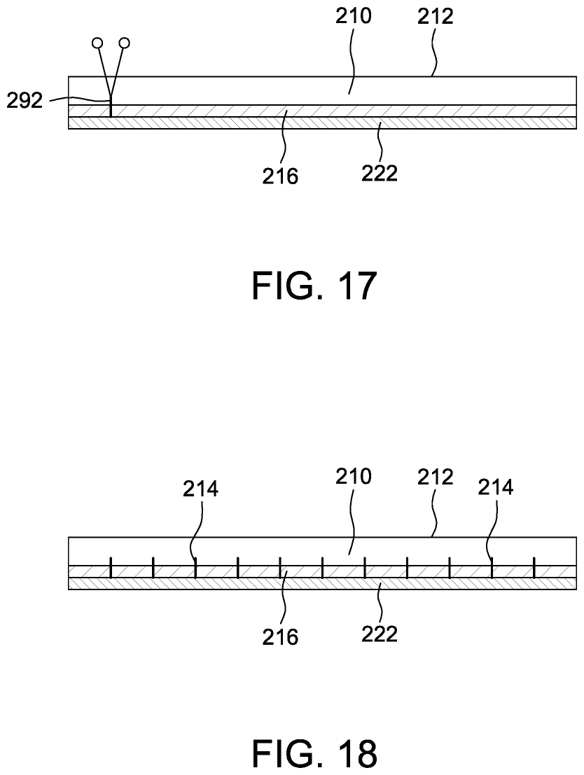

Next, as shown in FIG. 17, the wafer 110 is diced by laser. More specifically, laser beams 292 that can penetrate the wafer 210 illuminate the back surface 212 of the wafer 210. The laser beams 292 are focused at predetermined positions inside the wafer 210, and the wafer 210 is diced by the laser beams along predetermined cutting lines (not shown) on the front surface 211 of the wafer 210 so as to form a modified layer inside the wafer 210. FIG. 18 shows that the wafer 210 has a plurality of grooves 214 formed on the front surface 211 thereof after being diced by the laser beams 292.

In one embodiment, the laser beams 292 are invisible light with a wavelength of 1200-1500 nm.

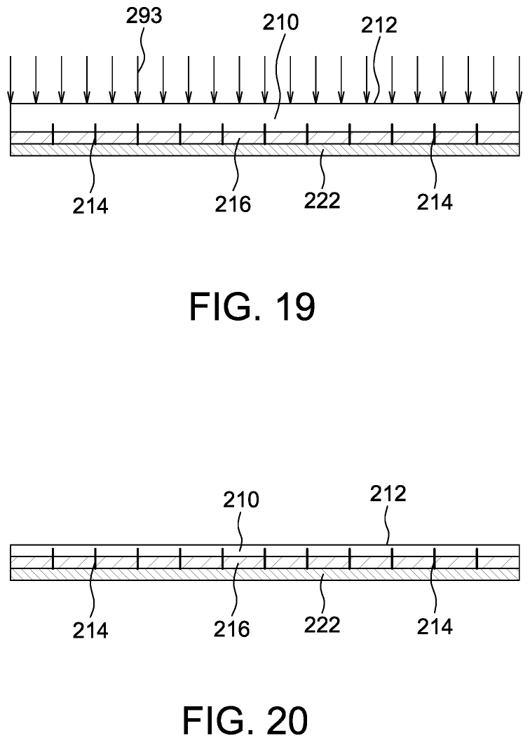

Afterwards, as shown in FIG. 19, a chemical solution or plasma process 293 is performed on the back surface 212 of the wafer 210 to ablate the wafer 210 so as to thin the wafer 210 to a required thickness. FIG. 20 shows that the wafer 210 has been thinned to the required thickness.

In one embodiment, the wafer 210 has a thickness of (20-300)±3 μm after subjection to the chemical solution or plasma process 293.

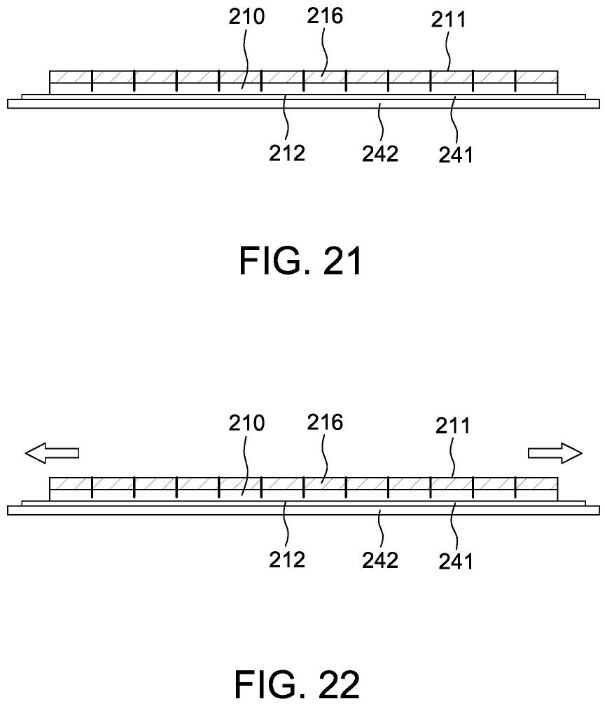

Next, as shown in FIG. 21, an attach film 241 is attached to the back surface 212 of the thinned wafer 210, and the wafer 210 is fixed to a frame 242. The protective film 222 is removed from the front surface 211 of the wafer 210.

Finally, as shown in FIG. 22, the frame 242 is fixed and outward forces are applied to the attach film 241 to expand the wafer 210 so that the wafer 210 is separated into a plurality of dies along the grooves 214.

According to the wafer thinning method of the present disclosure, the wafer may be thinned to a desired thickness without cracking the wafer.

Although the preferred embodiments of the disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A wafer thinning method, comprising:
providing a wafer having a front surface and a back surface opposite to the front surface;
grinding the back surface of the wafer with a grinding bit to thin the wafer to a predetermined thickness;
dicing the wafer with a dicing blade;
ablating the wafer by performing a chemical solution or plasma process on the back surface of the wafer to thin the wafer; and
separating the wafer into a plurality of dies.

2. The wafer thinning method as claimed in claim 1, further comprising:
before grinding the wafer, attaching a protective film to the front surface of the wafer;
before dicing the wafer, performing the following steps:
attaching an attach film to the back surface of the wafer;
fixing the wafer to a frame; and
removing the protective film from the front surface of the wafer.

3. The wafer thinning method as claimed in claim 1, further comprising:
before performing a chemical solution or plasma process, attaching a protective film to the front surface of the wafer;
after performing a chemical solution or plasma process, performing the following steps:
attaching an attach film to the back surface of the wafer;
fixing the wafer to a frame; and
removing the protective film from the front surface of the wafer.

4. The wafer thinning method as claimed in claim 1, wherein the dicing blade has a rotation speed of 30000-55000 rpm during dicing.

5. The wafer thinning method as claimed in claim 1, wherein the dicing blade scribes a plurality of dicing grooves on the front surface of the wafer, the depth of the dicing grooves is (25-350)±5 μm and the width of the dicing grooves is (10-60)±3 μm.

6. The wafer thinning method as claimed in claim 1, wherein the wafer has a thickness of (20-300)±3 μm after subjection to the chemical solution or plasma process.

7. A wafer thinning method, comprising:
providing a wafer having a front surface and a back surface opposite to the front surface;
grinding the back surface of the wafer with a grinding bit to thin the wafer to a predetermined thickness;
dicing the wafer with laser beams;
ablating the wafer by performing a chemical solution or plasma process on the back surface of the wafer to thin the wafer; and
separating the wafer into a plurality of dies.

8. The wafer thinning method as claimed in claim 7, further comprising:
after performing a chemical solution or plasma process, attaching an attach film to the back surface of the wafer and fixing the wafer to a frame.

9. The wafer thinning method as claimed in claim 7, wherein the laser beams have a wavelength of 1200-1500 nm.

10. The wafer thinning method as claimed in claim 7, wherein the wafer has a thickness of (20-300)±3 μm after subjection to the chemical solution or plasma process.
